(19) United States
(12) Patent Application Publication
(10) Pub. No.: US 2024/0142873 A1
(43) Pub. Date: May 2, 2024

(54) Photopolymerizable Composition

(71) Applicant: Xetos AG, Hohenbrunn (DE)

(72) Inventor: Frank Knocke, Ebersberg (DE)

(21) Appl. No.: 18/276,776

(22) PCT Filed: Feb. 11, 2022
(86) PCT No.: PCT/EP2022/053419

§ 371 Date: Aug. 10, 2023

(30) Foreign Application Priority Data
Feb. 11, 2021 (EP) 21156660.9

(51) Int. Cl. G03F 7/028; G03H 1/04

(52) U.S. Cl. CPC G03F 7/028; G03H 1/0443; G03H 1/0005; G03H 2260/12

(57) ABSTRACT

The present invention relates to photopolymerizable compositions and elements made therefrom, as well as their use. The photopolymerizable compositions are particularly suitable as recording material for optical elements with refractive index modulation, in particular holograms.

### CROSS-REFERENCE TO RELATED APPLICATIONS

This application is the United States national phase of International Application No. PCT/EP2022/053419 filed Feb. 11, 2022, and claims priority to European Patent Application No. 21156660.9 filed Feb. 11, 2021, the disclosures of which are hereby incorporated by reference in their entireties.

### BACKGROUND OF THE INVENTION

### Field of the Invention

The present invention relates to photopolymerizable compositions and elements made therefrom and as well to their use. The photopolymerizable compositions are particularly suitable as recording material for optical elements with refractive index modulation, especially for holograms.

### Description of Related Art

Numerous of holograms such as reflection holograms, embossing holograms or transmission holograms or volume holograms are known.

A volume hologram is produced, for example, by interfering two light waves of the same wavelength, also called object and reference beam, and exposing a holographic recording medium, usually photographic film, with the resulting interference pattern, which is usually an intensity pattern. The holographic exposure process and the duplication of the hologram (replication) are technically complex optical processes that require special application knowledge. Methods for creating holograms and the theory are described extensively in the literature [Howard M. Smith, “Principles of Holography”, Wiley (1969)] [Fred Unterseher, et al. “Holography Handbook: Making Holograms the Easy Way”, Ross Books (1982)] [Graham Saxby, “Practical Holography”, Inst, of Physics Pub. (2004)].

Known recording materials with different property profiles and applications are: Silver halide emulsions, cured dichromate gelatin, ferroelectric crystals, photochromic and dichroid materials, and photopolymers [Howard M. Smith, “Principles of Holography”, Wiley (1969).]. For high volume applications, materials of interest are those that can be easily integrated into hologram production and duplication equipment and that allow for easy holographic exposure and development. Photopolymers are considered particularly preferred due to their high efficiency, ease of handling and good storage stability. The best known photopolymers are from DuPont, e.g. Omnidex HRF 600 [S. M. Schultz, et al. “Volume grating preferential-order focusing waveguide coupler,” Opt. Lett, vol. 24, pp. 1708-1710, December 1999]. Omnidex materials belong to the class of self-developing photopolymer films based on radical polymerisation and monomer diffusion (see EP 0 324 480 A2).

Omnidex photopolymers have been further developed over the years, primarily with the aim of increasing the refractive index contrast and achieving a high diffraction efficiency in the film (see U.S. Pat. No. 4,942,112 A and DE 69032682 T2). Nevertheless, the application-relevant diffraction efficiencies of well over 2/3 are bought by a high proportion of thermoplastic binder.

In film production, the binder for the coating must be liquid. A solvent is used for this purpose, the evaporation of which leads to a sharp decrease in the layer thickness after coating. Depending on the solvent content, the wet layer to be applied is therefore significantly thicker than the resulting film layer. The solvent content is usually about 80%. In order to achieve a layer of 20 μm that can be exposed by volume holography, a wet layer of 100 μm must be applied in this case. The required high thickness of the wet layer prevents or complicates the use of known printing processes, such as flexographic or gravure printing. In screen printing, the use of fast-drying solvents can cause the mesh to stick together.

Moreover, the film can only be further processed or wound up when all the solvent has evaporated. In production, therefore, a long drying line must be set up with a health- and environment-friendly extraction system, as well as a dust- and explosion-proof environment. This effort means that film production and holographic exposure usually take place at separate locations and times.

In the case of binder-containing materials, thermal post-treatment (“annealing”) of the exposed and UV-fixed photopolymer is also necessary to achieve the maximum refractive index contrast (see DE 68905610 T2). Annealing is an additional time-consuming processing step that slows down, complicates and increases the cost of hologram production in addition to the time-consuming film production, and also limits the choice of substrate materials to those that are not temperature-sensitive.

Other photopolymer materials for volume holography have been produced by Polaroid (see U.S. Pat. No. 5,759,721 A), Fuji Photo Film (see EP 1 510 862 A2), Konica Minolta Medical & Graphic (see US 200505891 A1), Dai Nippon Printing (see EP 123151 A1), Nippon Paint (see EP 21 1615 A2), Nissan Chemical Industries (see US 20050068594 A1), Bayer (see WO 2010091795 A1, WO 2012062655 A2), Xetos (see WO 2003036389 A1) and InPhase Technologies (see US 2002142227 A1). The prior art features photopolymers that differ from Omnidex in their holographic properties or processing. Technical progress is documented by reduced oxygen sensitivity, reduced material shrinkage during exposure, adjusted spectral sensitivity, solvent-free film production, higher diffraction efficiency without annealing and/or better temperature and storage stability.

A newer and commercially available holographic photopolymer is the “Bayfol HX” film developed by Bayer Materialscience. This does not contain a thermoplastic binder but a polyurethane as the polymer matrix that holds the holographically exposable writing monomers. The polyurethane is formed by polyaddition from a polyisocyanate and polyol mixture. The reactive components are mixed together just before coating and cure on the carrier film. Although there is no high solvent content as with the previously described binder-containing materials, the curing time of up to one hour poses the same problem of providing a sufficiently long dust-free drying or curing section in the coating system.

As with all commercially available photopolymer films, the user cannot freely choose the carrier material and coat it himself, but must process the film structure supplied. In addition to the carrier film, there is also a laminating film on the light-sensitive film layer to prevent adhesion and contamination. Peeling off this film can cause a static charge that attracts dust particles. Since the film must be laminated to either glass or a master for exposure, where every particle of dust creates a flaw, an extremely dust-free environment is required for clean and flawless processing.

Photopolymer systems containing a polymeric binder or polymeric matrix form an essentially solid film layer. In contrast, binder-free systems that are essentially liquid until exposure have also been presented (see, for example, U.S. Pat. No. 3,993,485 A or N. Smirnova, Optics in Information Systems, February 2004, p. 9 or Xetos (see WO 2003036389 A1).

In most essentially solid monomer-binder/matrix photopolymers, unexposed writing monomers located in the area of the dark interference lines diffuse into the exposed polymerised areas after holographic laser exposure. This creates a refractive index difference whose spatial modulation corresponds to the interference pattern to be recorded. However, diffusion of the writing monomers in the solid matrix takes time. An increase in temperature can accelerate this process. DuPont specifies an annealing time of one hour at 120° C. for the OmniDex® material mentioned. In the case of the Bayfol HX material, the

patent applications (EP 2 372 454 A1 p.13 [0127], EP 2 219 073 A1 p.15 [0102]) specify a waiting time of 5 min before the material is finally completely cured with UV light.

For many production processes, however, the shortest possible times or the highest possible throughput and simple, cost-effective process control are required for the production of the holograms, so that cumbersome and time-consuming post-treatments or waiting times are a disadvantage.

For this reason, photopolymerizable compositions were developed that form an effective refractive index modulation already during laser exposure and can be immediately fixed with UV light, as described in EP 1 779 196 B1. Various triglycerides, such as castor oil, were used there.

The castor oil is an inert component that does not cross-link during exposure. This means that it can migrate out of the layer later. To reliably prevent this, the hologram layer is usually subsequently sealed with a UV varnish layer.

However, if the castor oil content is too high, this can happen during or shortly after exposure. Too high a proportion also leads to turbidity. The higher the castor content, the higher the exposure temperature must be to ensure a clear layer. However, increasing the temperature reduces the viscosity of the liquid material, which has a negative effect on holographic exposability. Therefore, there is an upper limit of the castor content and the exposure temperature, which must not be exceeded for a holographic exposure.

The brightness or the diffraction efficiency (“Beugungswirkungsgrad” BWG) n of volume holograms depends on their layer thickness d and on Δn. Δn denotes the amplitude of the refractive index modulation within the hologram layer. According to the coupled wave theory of Kogelnik (see; H. Kogelnik, The Bell System Technical Journal, Volume 48, November 1969, Number 9 Page 2909-Page 2947), the higher the Δn value, the thinner the layers can be to achieve a high BWG value. For reflection holograms from surface mirrors or Lippmann-Bragg holograms, where the refractive index modulation is parallel to the surface, the following relationship applies

$$η = {tanh}^{2} ( \frac{π \cdot Δ n \cdot d}{λ} ) , \qquad ( F - 1 )$$

where λ is the wavelength of the light.

### SUMMARY OF THE INVENTION

The object of the present invention is therefore the provision of a holographic recording material that avoids the disadvantages of known recording materials and, in particular, enables improved and very fast processing. The holographic elements produced from the recording material should also have the highest possible refractive index modulation and high long-term stability as well as thermal and mechanical stability. It should be possible to achieve Δn values of ≥0.01, preferably of ≥0.015 and particularly preferably of ≥0.02.

The object is solved according to the invention by a photopolymerizable composition comprising:
I) a first mixture A comprising
   a) at least one monomer M comprising at least one ethylenically unsaturated group,
   b) at least one triglyceride and/or a modified triglyceride,
   c) at least one photoinitiator,
   d) at least one aromatic aldehyde and/or aliphatic aldehyde; and
   e) optionally an additive.

### BRIEF DESCRIPTION OF THE DRAWINGS

FIG. 1 shows the schematic construction of a compact roll-to-roll machine for the production of sealed holographic contact copies from the photopolymerizable compositions of the present invention;

FIG. 2 shows the schematic exposure setup;

FIG. 3 shows the beam path; and

FIG. 4 shows the measurement curve with the corresponding measurement points of the first exposure of sample C.

### DESCRIPTION OF THE INVENTION

The triglyceride or the modified triglyceride is a component which does not crosslink during the light-induced polymer merge of the mixture. The mixture of at least one monomer and triglyceride preferably produces a clear mixture only above a certain temperature. Preferably, the photopolymerizable compositions according to the invention are clear above a temperature of 24° C. and more preferably above 22° C., while they are preferably milky below 16° C. and more preferably below 18° C. The monomer mixture of one or more monomers, as well as the resulting polymer, have a different refractive index than the non-crosslinking component. In holographic exposure, segregation of the components causes the triglyceride content to be higher in the dark areas of the interference pattern than in the light areas. This modulates the refractive index accordingly and creates a hologram.

Since the triglyceride or the modified triglyceride does not polymerize and can cause turbidity, its concentration must not be too high, otherwise a stable and clear hologram cannot be exposed.

Surprisingly, however, it turned out that by adding a certain aldehyde, the limit can be shifted upwards. This is advantageous because a higher delta-n value or a higher BWG can be achieved with thinner layers. Even a very small amount of this substance is sufficient.

The subsequent sweating out of the castor oil can also be prevented by adding substances that leave the cured layer faster than the oil. These can be small amounts of solvents such as ethanol or solids that sublimate or some UV initiators. Especially the UV initiators can be made to leave the layer faster than the castor oil by evaporation through a short intense UV flash. However, the UV initiators or other absorbers can also be used to accelerate the ejection of other substances by converting the absorbed energy into heat and passing it on. In principle, instead of the UV flash, all methods (pulsed light laser, infrared, microwaves, etc.) can be used that heat the material abruptly within a very short period of time via suitable absorber substances.

The release of the material naturally causes the layer to shrink, which is also noticeable in the hologram properties. This can be taken into account during exposure or used intentionally to create blue holograms with a green laser, for example.

The photopolymerizable composition according to the invention preferably comprises:
I) a first mixture A comprising
   a) at least one monomer M comprising at least one ethylenically unsaturated group,
   b) at least one triglyceride and/or a modified triglyceride,
   c) at least one photoinitiator,
   d) at least one aromatic aldehyde and/or aliphatic aldehyde; and
   e) optionally an additive,
II) at least one polyether.

The unexposed photopolymerizable composition becomes milky at low temperatures. It can best be exposed holographically at a temperature just above this segregation temperature. For prior art blends, the recommended exposure temperature was 25°-26° C.

By adding a mixture of polyether, the exposure temperature can advantageously be brought to a common room temperature of 21°-22° C. In addition, it also improves the delta-n value, so that a higher BWG (refractive index) can be achieved even with thinner layers. Now, a BWG value of over 80% can be safely achieved from as little as 12 μm, whereas previously this value was 15 μm.

Surprisingly, it was also found that the clarity of the exposed layer depends on the exposure time and intensity with which it is exposed or cured. If the layer is exposed quickly for less than 1s with sufficient intensity, the layer is less turbid than if it is exposed for several seconds with weaker powers. The haze can be measured and is expressed as a haze value in percent. The difference between the fast and slow exposed areas should reach at least 50%, preferably at least 60% and especially preferably at least 70% at an exposure temperature of 21° C. and a film thickness of 1 mm, measured according to the ASTM D standard procedure. Temperature also has an effect on turbidity. The lower the temperature, the more milky the result. Exposure of different areas at different temperatures can thus also make a difference or further enhance the intensity-dependent effect.

The sensitivity of the photopolymerizable composition should be better than 100 mJ/cm₂, preferably better than 50 mJ/cm₂ and particularly preferably better than 30 mJ/cm₂.

Preferably, the composition according to the invention does not require a solvent or thermal post-treatment. Exposure can take place immediately after application of the composition to a substrate. Wet application of the composition to the substrate can be performed by doctor blade, doctor blade or slot-dye coating. For thin layers smaller than 20 μm, known printing processes such as screen, gravure, engraving, pad or flexographic printing can also be used. Preferably, the photopolymerizable composition is laminated directly onto the master to be copied using a transparent and clear film. The layer thickness is adjusted either by the contact pressure and the lamination speed or by the slit width. When coating thick and rigid substrates such as glass plates, a spin coating process can be used. Application with an inkjet printing process or with a CNC-controlled dispensing device is also possible. Direct injection into cavities is also possible.

In particular, the photopolymerizable composition is also suitable for application to curved surfaces. It can also be pressed between two matching bodies and used simultaneously as a kit or adhesive.

The user also has the freedom to choose which substrates and layer structures to use, as the coating is done in the exposure unit. The solvent-free material can be exposed immediately after application. Multi-layer exposures are also no problem, as a new layer can be applied and holographically exposed after curing according to the same principles. This can be used, for example, to build up true-color holograms from three layers for the primary colors red, green and blue.

The use of triglycerides or modified triglycerides in the production of photopolymerizable compositions as holographic recording materials also has other significant advantages: The exposed photopolymer exhibits reduced surface adhesion because the triglyceride or modified triglyceride also acts as a release agent. The exposed hologram can therefore be easily removed from a substrate, such as glass, without leaving any residue. This property is also very favorable for mass production, because it allows the use of wearfree copy masters, such as conventional nickel shims with a fine holographic surface structure or volume holograms sealed with thin glass, for the production of contact copies. Due to the residue-free removal of the non-sticky layer, the cleaning effort remains low.

The photopolymerizable composition is particularly suitable for making contact copies. The fact that the liquid photopolymerizable composition is printed directly onto the master eliminates the need for index matching. This is the application of a liquid between the master and the hologram layer with approximately the same refractive index of the two layers. Index matching prevents the occurrence of disturbing interference phenomena (Newton rings) in the normal contact copying process with film materials. These are caused by reflections that occur especially in places where the two layers do not touch directly, e.g. due to a dust inclusion or a small unevenness, resulting in bubbles or air inclusions. In addition, the compensation of scratches and other irregularities from the substrate and master improves the optical quality of the copy. Small dust particles with a dimension smaller than the layer thickness are embedded in the liquid and do not create significant print and defect marks as with film materials. This significantly reduces waste and cleanroom demands on the production environment.

Advantageously, the liquid photopolymerizable composition can thus also be used as an index match material for the exposure of holographic film materials. Because it hardens during exposure, there is no need for cleaning or evaporation. In addition, the holographic recording is supported and enhanced by the combination of the two holographic recording materials, as a hologram is created in both layers.

Because the photopolymerizable composition adapts to any surface, in contrast to film materials, surface structures can be moulded at the same time as the hologram exposure and complex shaped surfaces can be used. The surface structures can be, in particular, embossed holograms or Fresnel structures. This makes it possible to physically and holographically copy both the surface structure and the volume holographic or optical information of the master in a single processing step.

In this way, optical elements such as prisms or lenses with integrated hologram structures can also be produced.

Because the photopolymerizable composition can be exposed immediately after application, compact coating and exposure times with very short transport distances and times between these two stations can be realized. This reduces the risk of unwanted pre-exposure due to ambient light. The requirement for a dark environment is therefore not great. The photopolymerizable composition can be applied and exposed within lmin, preferably within 20 s, particularly preferably within 5 s.

The photopolymerizable composition according to the invention comprises a first mixture A comprising at least one monomer M comprising at least one ethylenically unsaturated group, preferably a monomer M comprising at least two ethylenically unsaturated groups.

Particularly preferably, the photopolymerizable composition comprises a first mixture A comprising at least one monomer M comprising at least one ethylenically unsaturated group and a monomer M1 comprising at least two ethylenically unsaturated groups, wherein M1 preferably differs from M only by the second ethylenically unsaturated group.

The monomer comprising at least one ethylenically unsaturated group may have the following general structural units.

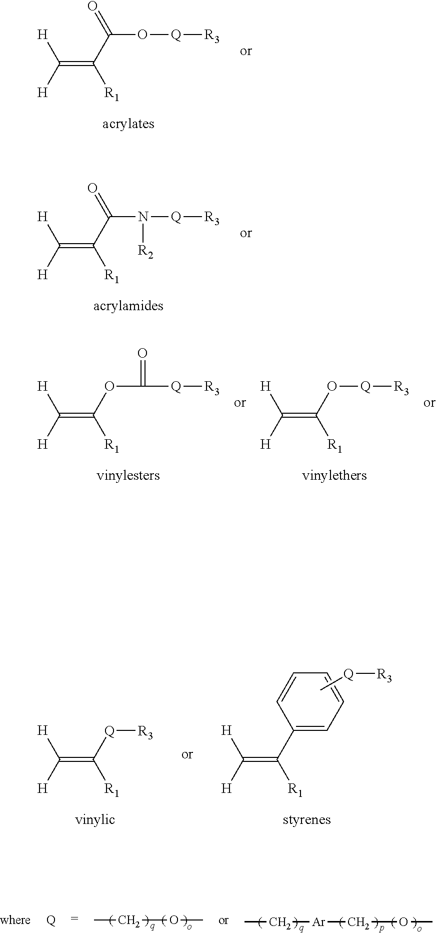

wherein q, p=0-12, preferably 1-12; o=0, 1; and Ar is a mono- or polynuclear substituted or unsubstituted aromatic or heterocyclic aromatic radical,
where the radical R₁ is H, methyl or ethyl and
wherein R₂ and R₃ are independently selected from the group consisting of alkyl, alkenyl, alkynyl, alkoxy, acyl and acyloxy radicals which may be straight or branched chain, unsubstituted or substituted, substituted or unsubstituted aryloxy radicals, substituted or unsubstituted aromatic radicals or heterocyclic radicals, unsubstituted or substituted alicyclic hydrocarbon radicals, aliphatic, aromatic and aliphatic-aromatic amino, carboxylic acid, amido and imido radicals, hydroxy, amino, cyano, nitro, halogen atoms or hydrogen atoms, and combinations of the foregoing radicals, wherein the substituted radicals may be substituted with C₁-C₁₂ alkyl, C₁-C₁₂ alkoxy, hydroxy, carboxy, carbonyl, amino, amido, imido radicals, halogen atoms, aromatic radicals or combinations thereof.

Examples of suitable monomers M are substituted or unsubstituted styrene monomers, acrylic acid, α-alkylacrylic acid, acrylic acid esters, α-alkylacrylic esters, the alcohol component of which can be a substituted or unsubstituted aliphatic or aromatic radical having 2-50 carbon atoms, acrylamides, α-alkylacrylamides, wherein alkyl is as defined above, vinyl esters, vinyl alcohol, vinyl ethers and other substituted vinyl monomers substituted with substituted or unsubstituted aliphatic or aromatic radicals having 2-50 carbon atoms.

Preferred examples of suitable monomers M are (meth)acrylic acid butyl ester, (meth)acrylic acid phenyl ester, (meth)acrylic acid benzyl ester, (meth)acrylic acid isobornyl ester, (meth)acrylic acid cyclohexyl ester, (meth)acrylic acid 2-phenoxyethyl ester, (meth)acrylic acid 1 H,1 H,2H,2H-perfluorooctyl ester, 2,2,2-trifluoroethyl (meth)acrylate, heptafluoropropyl (meth)acrylate, 1,1,1,3,3,3-hexyfluoroisopropyl (meth)acrylate, 2,2,3,3-tetrafluoropropyl (meth)acrylate), 2,2,3,3,4,4,4-heptafluorobutyl (meth)acrylate, 2,2,3,3,4,4,5,5-octafluoropentyl (meth)acrylate, acrylic acid N,N-diethylaminoethyl ester, acrylic acid ethoxyethyoxyethyl ester, acrylic acid 2-(p-chlorophenoxy)ethyl ester, p-chlorophenyl acrylate, 2-phenylethyl (meth)acrylate, pentachlorophenyl acrylate, phenyl acrylate, p-chlorostyrene, n-vinylcarbazole, 1-vinyl-2-pyrolidone, 2-chlorostyrene, 2-bromostyrene, methoxystyrene, phenol ethoxylate acrylate, 2-(p-chlorophenoxy)ethyl acrylate, 2-(1-naphthyloxy)ethyl acrylate, hydroquinone monomethacrylate and 2-[β-(N-carbazolyl)propionyloxy]ethyl acrylate.

Particularly preferred monomers M are N-vinyl carbazole, ethoxyethoxyethyl acrylate, 2-naphthyl acrylate, 2-phenoxyethyl acrylate, 2-phenoxyethyl methacrylate, phenol ethoxylate acrylate, 2-(p-chlorophenoxy)ethyl acrylate, p-chlorophenyl acrylate, phenyl acrylate, 2-phenylethyl acrylate, 2-(1-naphthyloxy)ethyl acrylate, t-butyl acrylate, isobornyl acrylate, cyclohexyl acrylate, N,N-diethylaminoethyl acrylate, acrylamide, ethoxyethoxyethyl acrylate, 1 H,1 H,2H,2H-perfluorooctyl methacrylate and pentafluoroethyl acrylate.

Preferably, the monomer M comprises at least two ethylenically unsaturated groups, hence the monomer is preferably difunctional.

Difunctional ethylenically unsaturated monomers have two C—C double bonds in the molecule, i.e. they contain e.g. two of the structural units indicated above. A difunctional ethylenically unsaturated monomer may contain, for example, two acrylate or methacrylate groups.

The monomer M in the photopolymerizable composition according to the invention may consist exclusively of one or more difunctional or higher functional monomers, i.e. the composition may be free of monofunctional ethylenically unsaturated monomers. The content of monomers M having at least two ethylenically unsaturated groups in the composition according to the invention is more than 5% by weight, preferably more than 10% by weight, and particularly preferably more than 20% by weight.

The use of difunctional or higher functional monomers leads in particular to a particularly high thermal and mechanical stability of the produced holographic elements and is especially advantageous in the production of reflexion holograms.

Preferred monomers M having at least two ethylenically unsaturated groups are ethoxylated bisphenol A diacrylates, in particular compounds of the following formula

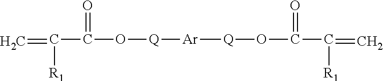

wherein R₁, Q and Ar have the meaning given above.

A particularly preferred monomer M is the compound of the following structural formula:

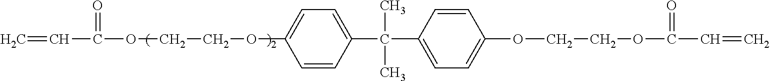

Preferably, the viscosity of the monomer M or monomer mixture is at least 900 mPa s at room temperature.

The viscosity of the photopolymerizable composition is also at least 900mPa s at 20° C., preferably 150 0mPa s and particularly preferably at least 2000 mPa s.

The viscosity can be determined with a plate-plate rotational rheometer (e.g. from Haake, type 006-2805). The material is placed between two coaxial circular plates, one of which rotates. The plates have a distance of e.g. 1 mm and a diameter of 35 mm. The viscosity can be determined from the measurement of the torque and the speed (e.g. 10 revolutions/s) (DIN53018, IS03210).

The photopolymerizable composition according to the invention comprises a first mixture A comprising a triglyceride and/or a modified triglyceride.

The suitable triglycerides are generally compounds of the following general structural formula

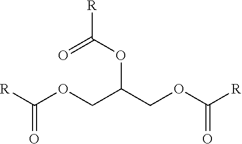

wherein each R, independently of the others, represents a fatty acid residue; preferably each R contains from 6 to 22, more preferably from 8 to 18, carbon atoms.

Naturally occurring oils or fats such as castor oil, coconut oil, palm kernel oil and mixtures thereof can also be used as triglycerides. Derivatives (e.g. hydrogenation products) of such natural fats and oils may also be used. Such naturally occurring oils or fats are or generally contain mixtures of various triglycerides.

A particularly preferred triglyceride is the triglyceride of ricinoleic acid, which is a major constituent of castor oil.

Preferably, the triglyceride is chosen such that the amount of the difference between the refractive index (n) of the ethylenically unsaturated monomer or monomer mixture and the refractive index of the triglyceride (i.e. |n(monomer)−n(triglyceride)|) at 20° C. is at least 0.02, more preferably at least 0.05, most preferably at least 0.07.

For example, ethyoxylated castor oils or their ricinoleic acids can be considered as modified triglyceride. Preferably, the modified triglyceride comprises ethoxylated triglycerides with 25 to 250 units based on ethylene oxide. For example, Hedipin R/2000 also known as “PEG-200 castoir oil”) may be used.

Hedipin R/2000 is produced by reacting castor oil with ethylene oxide in a molar ratio of 1:200. Castor oil is a mixture of triglycerides obtained from the seeds of Ricinus cornmunis. The main component of castor oil (>80%) is the triglyceride of ricinoleic acid. Hedipin R/2000 contains a mixture of polyethoxylated triglycerides, the polyethoxylated products of the triglyceride of ricinoleic acid being the main constituent. The polyethoxylated products of the triglyceride of ricinoleic acid comprise one or more of the compounds of formula A, B and C and mixtures thereof, as well as all stereoisomers thereof. Other components of Hedipin R/2000 may include polyoxyethylene ricinoleates, free polyethylene glycols and ethoxylated glycerols.

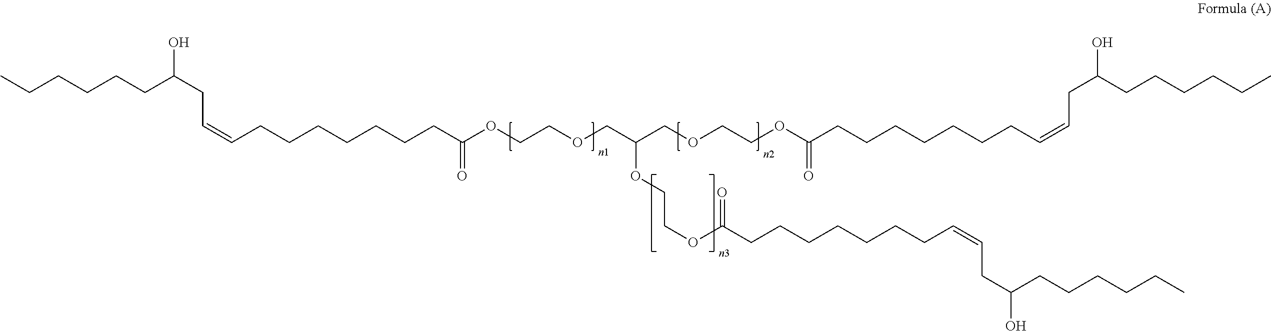

In formula (A), n1, n2 and n3 are independently an integer of 0-200, more preferably of 10-180, more preferably of 20-150, more preferably of 30-130, more preferably of 40-110, more preferably of 50-90, more preferably of 60-75, where n1+n2+n3=150-250.

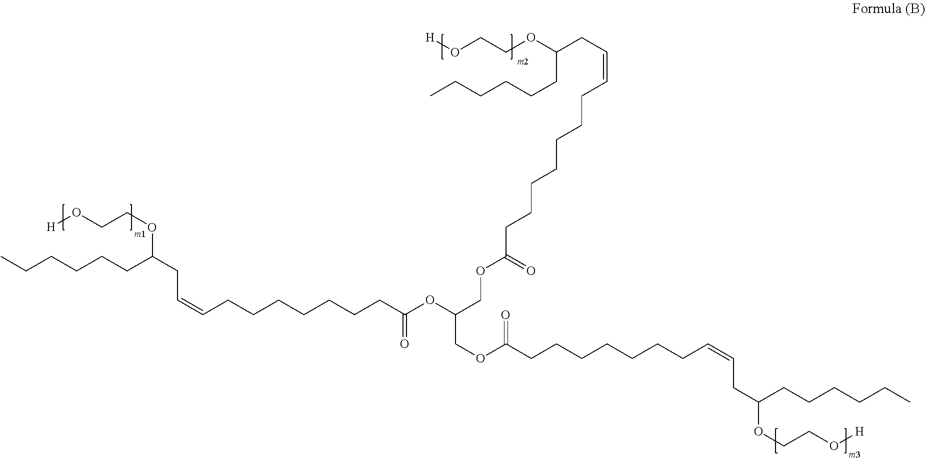

In formula (B), m1, m2 and m3 are independently an integer from 0-200, more preferably from 10-180, more preferably from 20-150, more preferably from 30-130, more preferably from 40-110, more preferably from 50-90, more preferably from 60-75, where m1+m2+m3=150-250.

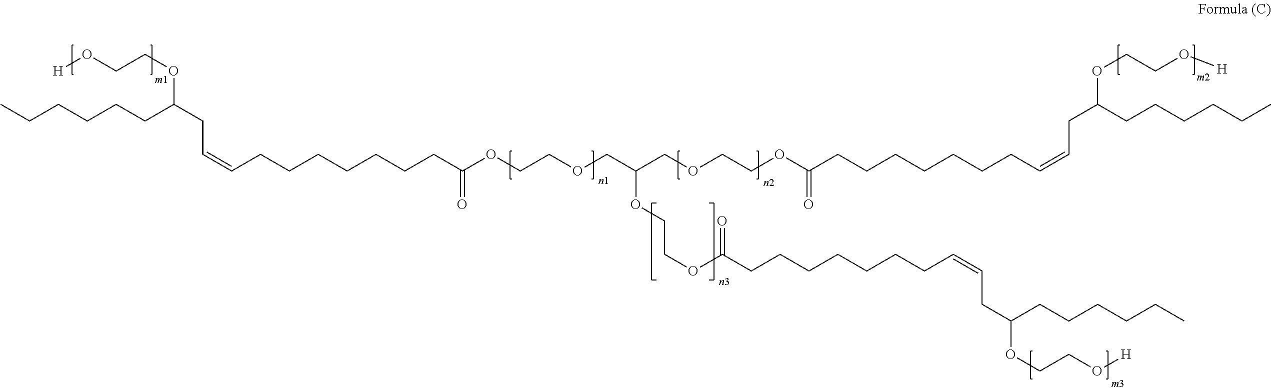

In formula (C), n1, n2 and n3 are each independently an integer of 0-200, more preferably of 5-175, more preferably of 10-150, more preferably of 15-125, more preferably of 20-100, more preferably of 20-75, more preferably of 25-40, where n1+n2+n3=50-150.

In formula (C), m1, m2 and m3 are each independently an integer from 0-200, more preferably from 5-175, more preferably from 10-150, more preferably from 15-125, more preferably from 20-100, more preferably from 20-75, more preferably from 25-40, n1+n2+n3=50-150.

Preferably, in formula (C), n1, n2, n3, m1, m2 and m3 are each independently an integer of 10-150, more preferably of 15-125, more preferably of 20-100, more preferably of 20-75, more preferably of 25-40, where n1+n2+n3+m1+m2+m3=150-250.

The photopolymerizable composition according to the invention comprises a first mixture A comprising at least one photoinitiator which preferably activates the polymerization of the monomer(s) M upon exposure to (actinic) radiation. This is preferably a radical-forming polymerization initiator.

Actinicity (actinic radiation) can be understood as the photochemical activity of electro-magnetic radiation of different wavelengths.

The term is used, for example, in evaluating the physiological consequences of laser light of different colors or the spectral sensitivity of photographic films and papers. In photo-chemistry, actinic chemicals are those that are sensitive to light or radiation.

Radical-forming polymerization initiators are known, see e.g. Timpe, H.J. and S. Neuenfeld, “Dyes in photoinitiator systems”, Kontakte (1990), pages 28-35 and Jakubiak, J. and J.F. Rabek, “Photoinitiators for visible light polymerization”, Polimery (Warsaw) (1999), 44, pages 447-461.

Suitable radical-forming polymerization initiators that can be activated by UV radiation and are generally inactive at temperatures up to 185° C. include the substituted or unsubstituted polynuclear quinones; these are compounds with two intracyclic carbon atoms in a conjugated carbocyclic ring system, e.g. 9,10-anthraquinone, 1-chloroanthraquinone, 2-chloroanthraquinone, 2-methylanthraquinone, 2-ethylanthraquinone, 2-tert-butylanthraquinone, octamethylanthraquinone, 1,4-naphthoquinone, 9,10-phenanthrenequinone, 1,2-benzanthraquinone, 2,3-benzanthraquinone, 2-methyl-1,4-naphthoquinone, 2,3-dichloronaphthoquinone, 1,4-dimethylanthraquinone, 2,3-dimethylanthraquinone, 2-phenylanthraquinone, 2,3-diphenylanthraquinone, sodium salt of anthraquinone α-sulfonic acid, 3-chloro-2-methylanthraquinone, retenquinone, 7,8,9,10-tetrahydronaphthacenequinone and 1,2,3,4-tetrahydrobenz[a]anthracene-7,12-dione. Other photoinitiators that are also useful, although some are thermally active at temperatures as low as 85° C., are described in U.S. Pat. No. 2,760,663 and include vicinal ketaldonyl alcohols such as benzoin, pivaloin, acyloin ethers, e.g., benzoin methyl and ethyl ether, α-hydrocarbyl-substituted aromatic acyloins including α-methylbenzoin, α-allylbenzoin and α-phenylbenzoin.

Photoreducible dyes and reducing agents such as those disclosed in U.S. Pat. Nos. 2,850,445 A, 2,875,047 A, 3,097,096 A, 3,074,974, 3,097,097 A, and 3,579,339 A, as well as dyes from the class of phenazines, oxazines and quinones; Michler's ketone, benzophenone, 2,4,5-triphenylimidazolyl dimers with hydrogen donors and mixtures thereof as described in U.S. Pat. Nos. 3,427,161 A, 3,479,185 A, 3,549,367 A, 4,311,783 A, 4,622,286 A, and 3,784,557 A can be used as photoinitiators. A useful discussion of dye sensitised photopolymerization can be found in “Dye Sensitized Photopolymerization” by D.F: Eaton in Adv. in Photochemistry, vol. 13, D.H. Volman, G.S. Hammond and K. Gollnick, eds, Wiley-Interscience, New York, 1986, pp. 427-487. Similarly, the cyclohexadienone compounds of U.S. Pat. No. 4,341,860 are useful as initiators. Suitable photoinitiators include CDM-HABI, i.e., 2-(o-chlorophenyl)-4,5-bis(m-methoxyphenyl)-imidazole dimer; o-CI-HABI, i.e., 2,2′-bis(o-chlorophenyl)-4,4′,5,5′-tetraphenyl-1,1′-biimidazole; and TCTM-HABI, i.e., 2,5-bis(o-chlorophenyl)-4-(3,4-dimethoxyphenyl)-1 H-imidazole dimer, each typically used with a hydrogen donor, e.g. 2-mercaptobenzoxazole.

Particularly preferred photoinitiators are UV photoinitiators such as IRGACURE® OXE-01 (1,2-octanedione-1[4-(phenylthio)-phenyl]-2-(O-benzoyloxime) and IRGACURE® OXE-02 (1-[9-ethyl-6-(2-methylbenzoyl)-9H-carbazol-3-yl]ethanone-O-acetyloxime from BASF AG, as well as OMNIRAD-MBF (methylbenzoyl formate), OMNIRAD-TPO (2,4,6-trimethylbenzoyl-diphenyl-phosphine oxide), OMNIRAD-TPO-L (ethyl-(2,4,6-trime-thylbenzoyl)-phenylphosphinate), OMNIRAD-1173 (2-hydroxy-2-methyl-1-phenylpropanone), OMNIRAD 1000 (mixture of 2-hydroxy-2-methyl-1-phenylpropanone (80%) and 1-hydroxycyclohexyl-phenylketone (20%)), OMNIRAD 184 (1-hydroxycyclohexyl-phenylketone), OMNIRAD 819 (bis(2,4,6-trimethylbenzoyl)phenylphosphine oxide), OMNIRAD 2022 (mixture of 2-hydroxy-2-methyl-1-phenylpropanone, bis(2,4,6-trimethylbenzoyl)phenylphosphine oxide and ethyl(2,4,6-trimethylbenzoyl)phenylphosphinate) and OMNICAT 440 (4,4′-dimethyl-diphenyl-iodonium-hexafluorophosphate), which are available from IGM Resins and are preferably used in an amount of 0.1 to 10% by weight.

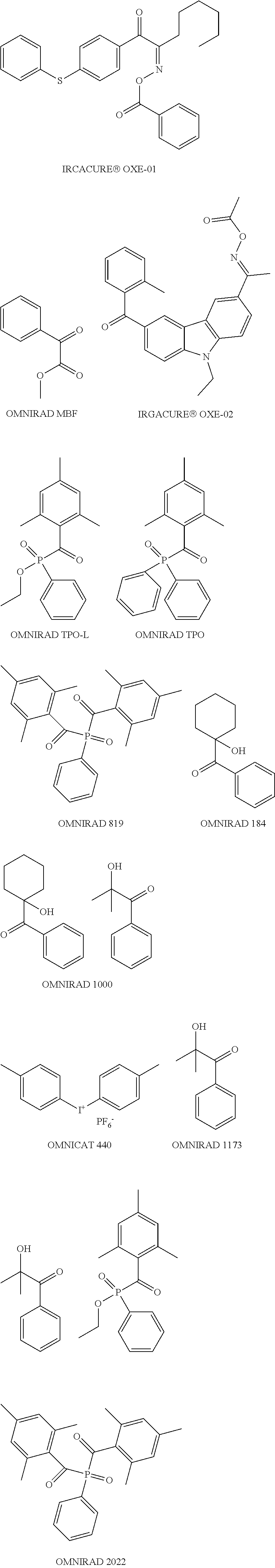

The photoinitiators mentioned above can be used alone or in combination.

A particularly preferred photoinitiator comprises the compound of the following structural formula I (co-photoinitiator) and dyes (sensitizers) such as methylene blue, and the sensitizers disclosed in U.S. Pat. Nos. 3,554,753 A, 3,563,750 A, 3,563,751 A, 3,647,467 A, 3,652,275 A, 4,162,162 A, 4,268,667 A, 4,454,218 A, 4,535,052 A and 4,565,769 A, as well as the dyes and co-photoinitiators referred to in application WO 2012062655 A2, which are expressly referred to herein. Particularly preferred sensitizing agents include the following: DBC, i.e., 2,5-bis[(4-diethylamino-2-methylphenyl)methylene]cyclopentanone; DEAW, i.e., 2,5-bis[(4-diethylaminophenyl)methylene]cyclopentanone; dimethoxy-JDI, i.e., 2,3-dihydro-5,6-dimethoxy-2-[(2,3,6,7-tetrahydro-1H,5H-benzo[i,j]iquinolizin-9-yl)methylene]-1H-inden-1-one; and safranin O, i.e., 3,7-diamino-2,8-dimethyl-5-phenyl-phenazinium chloride.

The compound with structural formula I, which was developed under the name “CGI 7460” by Ciba Specialty Chemicals Inc. and is now available from BASF AG under the name SEC LCA 1460, is presented as follows:

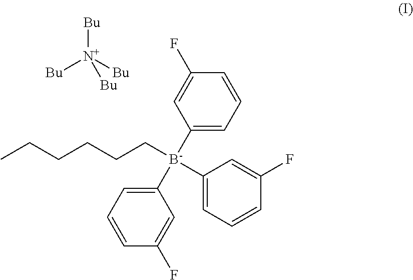

Particularly preferably, the dyes can be provided as dye concentrates (see Table 4) in a mixture without volatile solvents. This simplifies the preparation of the photopolymerizable compositions, as boiling out the volatile substances is no longer necessary and dosing is also easier and more accurate.

Preferably, the dye in the photopolymerizable compositions according to the invention is selected from the group consisting of acriflavins, diaminoacridins, rhodamine B, safranin-O, diethylsafranin and methylene blue.

Preferably, the co-photoinitiator in the photopolymerizable compositions according to the invention is selected from the group consisting of tetrabutylammonium tetrahexylborate, tetrabutylammonium triphenylhexylborate, tetrabutylammonium tris-(3-fluorophenyl)-hexylborate and tetrabutylammonium tris-(3-chloro-4-methylphenyl)-hexylborate or mixtures thereof.

Most preferably, the dye in the photopolymerizable compositions of the invention is selected from the group consisting of acriflavines, diaminoacridines, rhodamine B, safranin-O, diethylsafranin and methylene blue, and is combined with a co-photoinitiator selected from the group consisting of tetrabutylammonium tetrahexylborate, tetrabutylammonium triphenylhexylborate, tetrabutylammonium tris-(3-fluorophenyl)-hexylborate and tetrabutylammonium tris-(3-chloro-4-methylphenyl)-hexylborate or mixtures thereof.

In the composition according to the invention, the first mixture A further comprises at least one aromatic aldehyde and/or aliphatic aldehyde.

Preferably, the aromatic aldehyde is selected from the group consisting of vanillin, coniferylaldehyde, 2-methoxybenzaldehyde, 3-methoxybenzaldehyde, 4-methoxybenzaldehyde, 2-ethoxybenzaldehyde, 3-ethoxybenzaldehyde, 4-ethoxybenzaldehyde, 4-hydroxy-2,3-dimethoxy-benzaldehyde, 4-hydroxy-2,5-dimethoxy-benzaldehyde, 4-hydroxy-2,6-dimethoxy-benzaldehyde, 4-hydroxy-2-methyl-benzaldehyde, 4-hydroxy-3-methylbenzaldehyde, 4-hydroxy-2,3-dimethyl-benzaldehyde, 4-hydroxy-2,5-dimethyl-benzaldehyde, 4-hydroxy-2,6-dimethyl-benzaldehyde, 4-hydroxy-3,5-dimethoxy-benzaldehyde, 4-hydroxy-3,5-dimethyl-benzaldehyde, 3,5-diethoxy-4-hydroxy-benzaldehyde, 2,6-diethoxy-4-hydroxy-benzaldehyde, 3-hydroxy-4-methoxy-benzaldehyde, 2-hydroxy-4-methoxy-benzaldehyde, 2-ethoxy-4-hydroxy-benzaldehyde, 3-ethoxy-4-hydroxy-benzaldehyde, 4-ethoxy-2-hydroxy-benzaldehyde, 4-ethoxy-3-hydroxy-benzaldehyde, 2,3-di-methoxybenzaldehyde, 2,4-dimethoxybenzaldehyde, 2,5-dimethoxybenzaldehyde, 2,6-dimethoxybenzaldehyde, 3,4-dimethoxybenzaldehyde, 3,5-dimethoxybenzaldehyde, 2,3,4-trimethoxybenzaldehyde, 2,3,5-trimethoxybenzaldehyde, 2,3,6-trimethoxybenzaldehyde, 2,4,6-trimethoxybenzaldehyde, 2,4,5-trimethoxybenzaldehyde, 2,5,6-trimethoxybenzaldehyde, 2-hydroxybenzaldehyde, 3-hydroxybenzaldehyde, 4-hydroxybenzaldehyde, 2,3-dihydroxybenzaldehyde, 2,4-dihydroxybenzaldehyde, 2,4-dihydroxy-3-methylbenzaldehyde, 2,4-dihydroxy-5-methyl-benzaldehyde, 2,4-dihydroxy-6-methyl-benzaldehyde, 2,4-dihydroxy-3-methoxy-benzaldehyde, 2,4-dihydroxy-5-methoxy-benzaldehyde, 2,4-dihydroxy-6-methoxy-benzaldehyde, 2,5-dihydroxybenzaldehyde, 2,6-dihydroxybenzaldehyde, 3,4-dihydroxybenzaldehyde, 3,4-dihydroxy-2-methyl-benzaldehyde, 3,4-dihydroxy-5-methyl-benzaldehyde, 3,4-dihydroxy-6-methyl-benzaldehyde, 3,4-dihydroxy-2-methoxy-benzaldehyde, 3,4-dihydroxy-5-methoxy-benzaldehyde, 3,5-dihydroxybenzaldehyde, 2,3,4-trihydroxybenzaldehyde, 2,3,5-trihydroxybenzaldehyde, 2,3,6-trihydroxybenzaldehyde, 2,4,6-trihydroxybenzaldehyde, 2,4,5-trihydroxybenzaldehyde, 3,4,5-trihydroxybenzaldehyde, 2,5,6-trihydroxybenzaldehyde, 4-hydroxy-2-methoxybenzaldehyde, 4-dimethylaminobenzaldehyde, 4-diethylaminobenzaldehyde, 4-dimethylamino-2-hydroxybenzaldehyde, 4-diethylamino-2-hydroxybenzaldehyde, 4-pyrrolidinobenzaldehyde, 4-morpholinobenzaldehyde, 2-morpholinobenzaldehyde, 4-piperidinobenzaldehyde, 2-methoxy-1-naphthaldehyde, 4-methoxy-1-naphthaldehyde, 2-hydroxy-1-naphthaldehyde, 2,4-dihydroxy-1-naphthaldehyde, 4-hydroxy-3-methoxy-1-naphthaldehyde, 2-hydroxy-4-methoxy-1-naphthaldehyde, 3-hydroxy-4-methoxy-1-naphthaldehyde, 2,4-dimethoxy-1-naphthaldehyde, 3,4-dimethoxy-1-naphthaldehyde, 4-hydroxy-1-naphthaldehyde, 4-dimethylamino-1-naphthaldehyde, 4-dimethylamino-cinnamaldehyde, 2-dimethylaminobenzaldehyde, 2-chloro-4-dimethylaminobenzaldehyde, 4-dimethylamino-2-methylbenzaldehyde, 4-diethylamino-cinnamaldehyde, 4-dibutylamino-benzaldehyde, 4-diphenylamino-benzaldehyde, 4-dimethylamino-2-methoxybenzaldehyde, 4-(1-imidaz-olyl)-benzaldehyde, piperonal, 2,3,6,7-tetrahydro-1H,5H-benzo[ij]quinolizine-9-carboxaldehyde, 2,3,6,7-tetrahydro-8-hydroxy-1H,5H-benzo[ij]quinolizine-9-carboxaldehyde, N-ethylcarbazole-3-aldehyde, 2-formylmethylene-1,3,3-trimethylindoline (Fischer's aldehyde or tribase aldehyde), 2-indole aldehyde, 3-indole aldehyde, 1-methylindole-3-aldehyde, 2-methylindole-3-aldehyde, 1-acetylindole-3-aldehyde, 3-acetylindole, 1-methyl-3-acetylindole, 2-(1′,3′,3′-trimethyl-2-indolinylidene)-acetaldehyde, 1-methylpyrrole-2-aldehyde, 1-methyl-2-acetylpyrrole, 4-pyridinaldehyde, 2-pyridinaldehyde, 3-pyridinaldehyde, 4-acetylpyridine, 2-acetylpyridine, 3-acetylpyridine, pyridoxal, quinoline-3-aldehyde, quinoline-4-aldehyde, antipyrine-4-aldehyde, furfural, 5-nitrofurfural, 2-thenoyl-trifluoroacetone, chromone-3-aldehyde, 3-(5′-nitro-2′-furyl)-acrolein, 3-(2′-furyl)-acrolein and imidazole-2-aldehyde.

Particularly preferred is the aromatic aldehyde selected from the group consisting of 2,3-dihydroxybenzaldehyde, 2,4-dihydroxybenzaldehyde, 2,4-dihydroxy-3-methyl-benzaldehyde, 2,4-dihydroxy-5-methyl-benzaldehyde, 2,4-dihydroxy-6-methyl-benzaldehyde, 2,4-dihydroxy-3-methoxy-benzaldehyde, 2,4-dihydroxy-5-methoxy-benzaldehyde, 2,4-dihy-droxy-6-methoxy-benzaldehyde, 2,5-dihydroxybenzaldehyde, 2,6-dihydroxybenzaldehyde, 3,4-dihydroxybenzaldehyde, 3,4-dihydroxy-2-methyl-benzaldehyde, 3,4-dihydroxy-5-methyl-benzaldehyde, 3,4-dihydroxy-6-methyl-benzaldehyde, 3,4-dihydroxy-2-methoxy-benzaldehyde, 3,4-dihydroxy-5-methoxy-benzaldehyde, 3,5-dihydroxybenzaldehyde.

Very preferably, the aromatic aldehyde is selected from the group consisting of 2,4-dihy-droxybenzaldehyde, 2,5-dihydroxybenzaldehyde, 2,6-dihydroxybenzaldehyde and 3,5-dihydroxybenzaldehyde.

In order to adapt the photopolymerizable composition to the chosen processing method or field of application and to improve printability, surface adhesion, viscosity, film formation, flexibility, hardness, resistance to cold, heat and weathering, the composition or the first mixture A may contain various additives known per se.

Therefore, the first mixture A in the photopolymerizable composition optionally comprises an additive.

The additives include solvents, fillers, dyes, plasticizers, surfactants, common components used in photopolymer systems, polymeric binders, wetting agents, levelling agents, defoamers, adhesion promoters, surface additives, nanoscale particles, optical brighteners or mixtures thereof.

These should be easy to mix in and should not worsen the diffraction efficiency. Non-volatile substances can even permanently improve the diffraction efficiency in thin films, in particular by choosing additives that increase the refractive index difference between the ethylenically unsaturated monomer and the other components of the photopolymerizable composition. If the triglyceride component has a lower refractive index than the ethylenically unsaturated monomer component, the additive(s) should also have as low a refractive index as possible. Therefore, in addition to known polymers with a low refractive index such as polyvinyl acetate, fluorinated or silanized polymers are particularly suitable in this case. In order to achieve good diffusion properties, the molecular weight of the additives considered should not be too high.

The additives mentioned above and specified in detail below can generally be used in an amount of 0.01 to 20% by weight, preferably 0.01 to 10% by weight.

The photopolymerizable composition or the first mixture A may contain a plasticizer to enhance the modulation of the refractive index of the imaged composition. Plasticizers may be used in amounts ranging from about 0.01% to about 10% by weight, preferably from 5% to about 10% by weight. Suitable plasticizers include triethylene glycol, triethylene glycol diacetate, triethylene glycol dipropionate, triethylene glycol dicaprylate, triethylene glycol dimethyl ether, triethylene glycol bis(2-ethylhexanoate), tetraethylene glycol diheptanoate, polyethylene glycol, polyethylene glycol methyl ether, isopropyl naphthalene, diisopropyl naphthalene, polypropylene glycol, glyceryl tributyrate, diethyl adipate, diethyl sebacinate, dibutyl suberinate, tributyl phosphate, tris(2-ethylhexyl) phosphate, Brij® 30 [C₁₂H₂₅(OCH₂CH₂)₄OH], Brij® 35 [C₁₂H₂₅(OCH₂CH₂)₂₀OH], and n-butyl acetate.

Particularly preferred plasticizers are polyethylene glycol, triethylene glycol diethyl hexanoate (3G8), triethylene glycol dicaprylate, tetraethylene glycol diheptanoate, diethyl adipate, Brij® 30 and tris(2-ethylhexyl) phosphate.

If desired, other common components used in photopolymer systems may be used with the compositions and elements of the present invention. These components include: Optical brighteners, ultraviolet radiation absorbing material, thermal stabilizers, hydrogen donors, oxygen scavengers and release agents. These additives may also include polymers or co-polymers.

Useful optical brighteners include those disclosed in U.S. Pat. No. 3,854,950 A. A preferred optical brightener is 7-(4′-chloro-6′-diethylamino-1′,3′,5′-triazin-4′-yl)amino-3-phenyl-coumarin. Ultraviolet radiation absorbing materials useful in the present invention are also disclosed in U.S. Pat. No. 3,854,950 A.

Useful thermal stabilizers include: Hydroquinone, phenidone, p-methoxyphenol, alkyl-and aryl-substituted hydroquinones and quinones, tert-butylcatechol, pyrogallol, copper resinate, naphthylamines, β-naphthol , copper(I) chloride, 2,6-di-tert-butyl-p-cresol, phenothiazine, pyridine, nitrobenzene, dinitrobenzene, p-toluchinone and chloranil. Also useful are the dinitroso-dimers described in U.S. Pat. No. 4,168,982 A. Typically, a thermal polymerization inhibitor is also present to increase stability during storage of the photo-polymerizable composition.

Hydrogen donor compounds useful as chain transfer reagents include: 2-mercaptobenzoxazole, 2-mercaptobenzothioazole, etc., as well as various types of compounds such as. (a) ethers, (b) esters, (c) alcohols, (d) compounds containing allylic or benzylic hydrogen such as cumene, (e) acetals, (f) aldehydes, and (g) amides, as disclosed in column 12, lines 18 to 58 in U.S. Pat. No. 3,390,996 A, which is specifically referred to herein.

Compounds that have proven useful as release agents are described in U.S. Pat. No. Patent 4.326,010 A. A preferred release agent is polycaprolactone.

The photopolymerizable composition or the first mixture A may also contain one or more polymeric binders selected from the group comprising polymethyl methacrylate and polyethyl methacrylate, polyvinyl esters, such as polyvinyl acetate, polyvinyl acetate/acrylate, polyvinyl acetate/methacrylate and partially hydrolyzed polyvinyl acetate, ethylene/vinylacetate copolymers, vinyl chloride/carboxylic acid ester copolymers, vinyl chloride/acrylic acid ester copolymers, polyvinyl butyral and polyvinyl formal, butadiene and isoprene polymers and copolymers and polyethylene oxides of polyglycols having an average molecular weight of about 1,000 to 1,000,000 g/mol, epoxides, such as epoxides containing acrylate or methacrylate residues, polystyrenes, cellulose esters, such as cellulose acetate, cellulose acetate succinate and cellulose acetate butyrate, cellulose ethers, such as methyl cellulose and ethyl cellulose, polycondensates, such as polycarbonates, polyesters, polyamides, such as N-methoxymethyl polyhexamethylene adipamide, polyimides, polyurethanes. The polymeric binders mentioned can be used, for example, in an amount of 0.001 to 10% by weight, based on the total weight of the composition.

The photopolymerizable composition or the first mixture A may also comprise one or more wetting agents (in particular fluorocarbon polymers, such as Schwego-Fluor 8038™, or fluorosurfactants, such as 3M Fluorad FC-4430™), levelling agents (in particular glycolic acid n-butyl esters or polyether-modified polydimethylsiloxanes, such as ADDID 130™), defoamers (in particular defoamers based on fluorosilicone oil, such as ADDID 763™) adhesion promoters (in particular diamino-trimethoxy-functional silane adhesion promoters, such as ADDID 900™ or glycidyl trimethoxy trifunctional silane coupling agents, such as ADDID 911™, vinyl triethyoxysilane or 3-methacryloxypropyl trimethoxysilane), or surface additives (in particular polyether-modified acryl-functional polydimethyl siloxanes, such as BYK-UV 3500™polyether-modified polydimethylsiloxanes such as BYK-UV 3510™ or polyether-modified acryl-functional polydimethylsiloxanes such as BYK-UV 3530™). The products mentioned with the trade names “ADDID” and “BYK” are available from Wacker and BYK Chemie, respectively.

The photopolymerizable composition or the first mixture A may also contain nanoscale particles such as TiO₂, SiO₂ or Au, which may optionally be coupled to monomers (such materials are available, for example, under the trade name “Nanocryl”).

Preferably, the additive can be an amine synergist. An amine synergist in combination with other photoinitiators can increase the curing speed of UV coatings (see DE 60216490 T2).

Preferably, the additive can be a peroxide. A thermally activatable peroxide, in combination with other photoinitiators, can improve the curing of UV coatings, especially in shaded areas (see U.S. Pat. No. 5,017,406 A or DE 60030223 T2).

Preferably, the additive can also be a marker selected from fluorescent pigments or lanthanide compounds. For example, europium or terbium trisdipicolinate complexes can be used as lanthanide compounds.

For the purposes of the present invention, a marker is understood to be a forensically detectable substance that can be used to determine the authenticity or origin of a product or its producer or seller. Provided that the layers to be produced are thick enough to embed the corresponding microparticles, small individualized particles, colored microplastic also known as taggant, can also be introduced.

Preferably, the photopolymerizable composition is liquid at standard pressure in a range from 15° C. to 150° C., more preferably 20° C. to 120° C.

Preferably, the polyether comprises a polyether based on a Poly(ethylene glycol)-block-po/y(propylene glycol)-block-po/y(ethylene glycol)

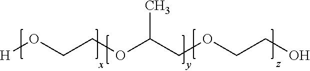

In the formula, x=1-500, y=1-500 and z=1-500, preferably x=1-200, y=1-200 and z=1-200, more preferably x=5-100, y=5-100 and z=5-100. The number average molecular weight is preferably 500-2000, more preferably 750-1500, most preferably 900-1300
or
Poly(bisphenol A-co-epichlorohydrin) with glycidyl end groups (“gylcidyl end capped”)

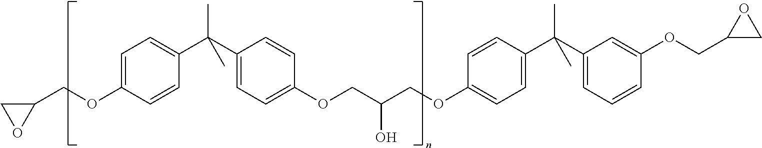

In the formula, n=1-500, preferably n=1-200, more preferably n=5-100. The number average molecular weight is preferably 500-2000, more preferably 750-1500, most preferably 900-1300. The epoxy equivalent weight is preferably 100-1000, more preferably 250-750, most preferably 500-600.

Preferably, the photopolymerizable composition according to the invention comprises:
I) 60-95% by weight of a first mixture A comprising
   a) at least one monomer M comprising at least one ethylenically unsaturated group,
   b) at least one triglyceride and/or modified triglyceride,
   c) at least one photoinitiator,
   d) at least one aromatic aldehyde and/or aliphatic aldehyde; and
   e) optionally an additive,
II) 5-40% by weight of at least one polyether, the amounts of I) and II) adding up to 100% by weight.

Particularly preferred is a photopolymerizable composition comprising:
I) 60-95% by weight of a first mixture A comprising
   a) 70-98% by weight of at least one monomer M comprising at least one ethylenically unsaturated group,
   b) 0.5-24% by weight of at least one triglyceride and/or modified triglyceride,
   c) 0.1-5% by weight of at least one photoinitiator,
   d) 0.1-2% by weight of at least one aromatic aldehyde and/or aliphatic aldehyde and
   e) 0 to 10% by weight of an additive, preferably 0.01 to 10% by weight of an additive, the amounts of a) to e) adding up to 100% by weight, and
II) 5-40% by weight of at least one polyether, the amounts of I) and II) adding up to 100% by weight.

Very particularly preferred is a photopolymerizable composition comprising:
I) 60-95% by weight of a first mixture A comprising
   a) 70-98% by weight of at least one monomer M comprising at least one ethylenically unsaturated group,
   b) 0.5-24% by weight of at least one triglyceride and/or modified triglyceride,
   c) 0.1-5% by weight of at least one photoinitiator and a further photoinitiator of a co-photoinitiator with a dye, wherein the dye is selected from the group consisting of acriflavines, diaminoacridines, rhodamine B, safranin-O, diethylsafranin and methylene blue, and the co-photoinitiator is selected from the group consisting of tetrabutylammonium tetrahexylborate, tetrabutylammonium triphenylhexylborate, tetrabutylammonium tris-(3-fluorophenyl)-hexylborate and tetrabutylammonium tris-(3-chloro-4-methylphenyl)-hexylborate, or mixtures thereof.
   d) 0.1-2% by weight of at least one aromatic aldehyde and/or aliphatic aldehyde and
   e) 0 to 10% by weight of an additive, preferably 0.01 to 10% by weight of an additive, the amounts of a) to e) adding up to 100% by weight, and
II) 5-40% by weight of at least one polyether based on a
Poly(ethylene glycol)-block-poly(propylene glycol)-block-poly(ethylene glycol)

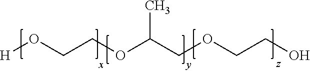

in which formula x=1-500, y=1-500 and z=1-500, preferably x=1-200, y=1-200 and z=1-200, particularly preferably x=5-100, y=5-100 and z=5-100 and/or the number average molecular weight is preferably 500-2000, more preferably 750-1500, particularly preferably 900-1300,
or
Poly(bisphenol A-co-epichlorohydrin) with glycidyl end groups (“gylcidyl end capped”)

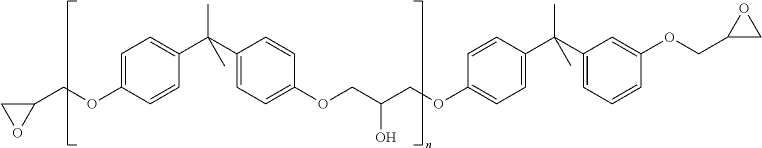

in which formula n=1-500, preferably n=1-200, particularly preferably n=5-100 and/or the number average molecular weight is preferably 500-2000, more preferably 750-1500, particularly preferably 900-1300 and/or the epoxy equivalent weight is preferably 100-1000, more preferably 250-750, particularly preferably 500-600,
the amounts of I) and II) being 100% by weight.

In particular, preferred is a photopolymerizable composition comprising:
I) 60-95% by weight of a first mixture A comprising
   a) 70-98% by weight of at least one monomer M comprising compounds of the following formula

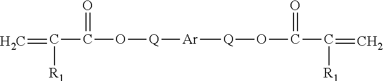

wherein R₁, Q and Ar have the meaning given above,
b) 0.5-24% by weight of at least one triglyceride and/or modified triglyceride, wherein the modified triglyceride is selected from the group consisting of the above formulae (A), (B), (C) and mixtures thereof,
   c) 0.1-5% by weight of
      at least one photoinitiator selected from the group consisting of 1,2-octanedi-one-1-[4-(phenylthio)-phenyl]-2-(O-benzoyloxime), (1-[9-ethyl-6-(2-methylbenzoyl)-9H-carbazol-3-yl]ethanone-O-acetyloxime, methyl benzoyl formate, 2,4,6-trimethylbenzoyl diphenyl phosphine oxide, ethyl (2,4,6-trimethylbenzoyl) phenyl phosphinate, 2-hydroxy-2-methyl-1-phenyl propanone, a mixture of 2-hydroxy-2-methyl-1-phenylpropanone (80%) and 1-hydroxycyclohexyl-phenyl ketone (20%), 1-hydroxycyclohexyl-phenyl ketone), bis(2,4,6-trimethylbenzoyl)phenyl phosphine oxide), a mixture of 2-hydroxy-2-methyl-1-phenylpropanone and bis(2,4,6-trimethylbenzoyl)phenylphosphine oxide and ethyl(2,4,6-trimethylbenzoyl)phenylphosphinate), 4,4′-dimethyl-diphenyl-iodonium hexafluorophosphate,
      and
      at least one photoinitiator of a co-photoinitiator with a dye, wherein the dye is selected from the group consisting of acriflavines, diaminoacridines, rhodamine B, safranin-O, diethylsafranin and methylene blue, and the co-photoinitiator is selected from the group consisting of tetrabutylammonium tetrahexylborate, tetrabutylammonium triphenylhexylborate, tetrabutylammonium tris-(3-fluorophenyl)-hexylborate and tetrabutylammonium tris-(3-chloro-4-methylphenyl)-hexylborate, or mixtures thereof.
   d) 0.1-2% by weight of at least one aromatic aldehyde
selected from the group consisting of 2,4-dihydroxybenzal dehyde, 2,5-dihydroxybenzaldehyde, 2,6-dihydroxybenzaldehyde, and 3,5-dihydroxybenzaldehyde,
   e) 0 to 10% by weight of an additive, preferably 0.01 to 10% by weight of an additive, the amounts of a) to e) adding up to 100% by weight, and
II) 5-40% by weight of at least one polyether based on a
Poly(ethylene glycol)-block-poly(propylene glycol)-block-poly(ethylene glycol)

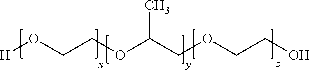

in which formula x=1-500, y=1-500 and z=1-500, preferably x=1-200, y=1-200 and z=1-200, particularly preferably x=5-100, y=5-100 and z=5-100 and/or the number average molecular weight is preferably 500-2000, more preferably 750-1500, particularly preferably 900-1300,
or
Poly(bisphenol A-co-epichlorohydrin) with glycidyl end groups (“gylcidyl end capped”)

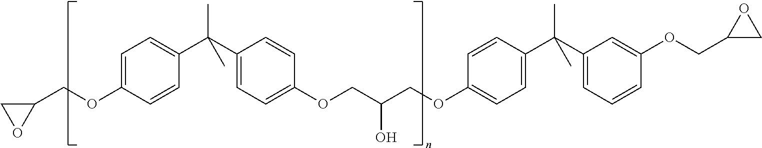

in which formula n=1-500, preferably n=1-200, particularly preferably n=5-100 and/or the number average molecular weight is preferably 500-2000, more preferably 750-1500, particularly preferably 900-1300 and/or the epoxy equivalent weight is preferably 100-1000, more preferably 250-750, particularly preferably 500-600, the amounts of I) and II) being 100% by weight.

In a further embodiment, the invention comprises an element comprising a component obtainable by exposing the photopolymerizable composition according to the invention to (actinic) UV/VIS radiation.

Preferably, the element according to the invention comprises a component having transparent and/or translucent regions.

If the photopolymerizable composition is exposed to a light source of at most 50 mW/cm₂ for a period of at least 1 s to 5 min, preferably from 2 s to 2 min, it can become milky. The result is a frosted screen whose scattering properties can be specifically and locally altered by the chosen exposure method (duration, intensity, temperature, etc.). It also makes a difference whether coherent laser light (speckles) or white or UV light is used for exposure. The speckle size can be used, for example, to selectively adjust the graininess. The achievable resolution is very high. Therefore, components can preferably be provided that comprise transparent and/or translucent areas.

With a mask exposure, any structures, texts and images can thus be created that can be recognized independently of a holographic reproduction via their mattness.

In a further embodiment, the invention relates to the use of the element according to the invention as a foil, lens, grating, prism, mirror, beam splitter, diffuser, surface relief, membrane, filter or sensor.

By exposing with a directional beam and a line pattern, milky lamellae that are vertically or obliquely spaced at regular intervals in the layer can be exposed to create a louvre film. This film is transparent in a direction corresponding to the angle of exposure and milky otherwise. Such a film can be used, for example, as an eye protection film for screens.

The whole thing can also be combined with holographic properties by exposing the areas that have not yet been exposed to light quickly and transparently in a holographic manner. The resulting film then reacts to a certain angle of illumination, for example. Beam deflection and scattering can be coordinated. The use of several layers that are applied one after the other and exposed differently is also conceivable.

In addition, a surface, e.g. a lens structure, can be moulded at the same time. In this way, it is possible to create structures that, for example, bundle the light from an LED array and reproduce it as a directional light beam and other light from LEDs that are not in the lenticular array as scattered light. This scattering can be amplified by the matte areas outside the lens beam paths. The use of a honeycomb structure with matte walls would be a possible embodiment.

One application would be light sources that imitate the natural sky and emit direct directional white-yellow sunlight as well as blue scattered light. The LED array of this artificial “skylight” could of course still vary the brightness and color locally, as with a screen, so that different lighting moods, times of day, cloudy skies, and passing clouds could be simulated.

The blue light could also be filtered from the directed white light beam by a reflection hologram and directed to the scattering centres or surfaces. All this, impression, light bundling, scattering and hologram can be realized with this photopolymer material in one exposure process or combined by repeated application and exposure in several layers.

Directional and diffused light is also needed in automobiles. Directional light for the headlights that illuminate the road and diffused light, such as for turn signals, brake lights or rear lights that are to be visible to other road users over a wide angle range. By using the special foil described and explained above, a headlamp, for example, could be constructed in such a way that it also fulfils the function of an indicator over its entire surface. The headlamp would be able to emit the directional headlamp light and, if necessary, yellow light scattered in all directions at the same time.

Particularly preferred is an element according to the invention comprising a hologram obtainable by exposing the photopolymerizable composition according to the invention to modulating radiation carrying holographic information.

Particularly preferred is an element comprising a hologram, wherein the hologram is provided with a sealing layer.

Preferably, a swelling agent is applied to the sealing layer. A swelling agent in the sense of the present invention is a substance that causes shrinkage or swelling of the hologram by diffusion.

Because the cured photopolymerizable composition has a limited elasticity, it can only shrink and swell within a certain range. When the lower limit is reached, the remaining castor oil can no longer escape on its own.

Conversely, however, substances can also diffuse in and swell the layer produced from the photopolymerizable composition according to the invention. For example, a green reflection hologram can be transformed into a red one in this way.

The same methodology can also be used with the flash light. Applied substances evaporate and penetrate the layer at lightning speed. Surprisingly, this also works when the photopolymer layer is already sealed by a UV varnish layer. Since this sealing layer prevents the castor oil from escaping, no exchange takes place and the swollen areas remain permanently intact.

This can be wonderfully used to subsequently individualize a finished hologram. The swelling agent is applied using a common inkjet printing process, for example. Due to the subsequent strong UV flash, the effective substances evaporate and create a swelling and local colour changes in the hologram by penetrating where they have been applied. The introduced information can be, for example, a picture, a number or an inscription. Since these changes cannot be reversed and only affect the hologram, this fast and simple process is a good way to increase the counterfeit protection of ID cards, seals or vignettes. Especially for products that are still individualized at the point of issue and where this must be easy to carry out.

Instead of an inkjet printer and flash, a dye-sublimation printer can also be used, which vaporizes the swelling substances via an appropriate printer ribbon.

A particularly large difference can be achieved if the hologram has been shrunk beforehand. A previously pure green hologram, which was only exposed with a green laser, can thus subsequently show blue, green and red areas through shrinking and swelling.

This can also be used for technical purposes, e.g. for a reflection hologram, which should have fine red, green and blue hologram lines for the reproduction of a colored projection for the primary colors.

With thick layers, a concentration gradient can arise. The penetrated material then swells the upper layer more than the deep layers. This leads to a broadening of the absorption peak in the absorption spectrum. A double peak is also possible if the swelling area ends abruptly and the strength of the swelling does not gradually decrease.

A broadening of the peak means that a larger wavelength range is reflected and also that the reproduction angle for a certain wavelength becomes wider. The possibility to change these important parameters of a hologram afterwards is useful for many technical applications, e.g. for HUDs that should also function under a larger reproduction or viewing angle.

Since the photopolymerizable composition is preferably liquid under standard conditions and is hardened during exposure, this is associated with a certain shrinkage, as with most substances that make such a phase transition. Due to this hardening shrinkage, a relief is created on the surface during holographic exposure, which corresponds to the interference pattern. This can be explained by the fact that the inert component, which does not undergo a phase change, occurs more frequently in the dark, initially unexposed areas of the interference pattern and therefore, less shrinkage is shown there.

It is remarkable that when a reflection hologram is exposed to light, the surface has a rather sawtooth-shaped and non-sinusoidal structure. This structure can therefore serve very well as a template for a nickel shim for the production of embossed holograms. The masters for these shims are usually produced using a photoresist lacquer and a special etching process. The generation of the desired sawtooth structures is not easy and is called the blaze process.

With the photopolymerizable composition, on the other hand, it is much easier and the complex etching process can be dispensed with. The shrinkage and the depth of structure can be further enhanced, as already described above, by the small addition of solvents. Washing out castor oil by bathing it in an ethanol-water solution also enhances the profile.

A layer that is actually exposed as a reflection hologram can also be used directly as a transmission hologram thanks to the surface structures that are formed. With this method, it is very easy to realize an inline transmission hologram, for example. The exposure setup could look like this: a parallel light beam passes vertically through the photopolymerizable composition, hits a concave mirror directly behind it and reflects the light back, which then interferes with the incident wave. If the finished hologram is now illuminated with the plane wave, part of the light is diffracted by the resulting surface relief and focused behind the plate. At the point where the focused light and the plane wave have an intensity ratio of 50%, a very light-intensive volume transmission hologram can now be recorded very well in a second step.

This trick greatly simplifies the production of such a master. Otherwise, the exposure setup would have required two beam paths and a semi-transparent mirror, not to mention the complex post-treatment of a photoresist layer.

It is interesting to note that height structures are also created with mask exposures. And this depends on which area was exposed with laser light and which areas were only exposed with UV light. The type of exposure can also create reliefs. Depending on the resolving power of the mask technique, any structures can be created. It is conceivable to use this technique to create microstructures.

Particularly preferred is the use of the element according to the invention for a head-up display, data glasses, a light guidance system, a spectrometer, a detection system, a security element or a label.

Depending on the swelling chemicals used, their distribution in the layer can still change over time as a function of temperature. For some substances, it can be observed that the peaks of a double peak move towards each other over time and merge. Often this effect only occurs when a certain temperature value, e.g. the melting point of this chemical, is exceeded.

Since the spectrometric measurement is very easy to interpret, the presence or absence of a double peak or the wavelength shift of a single peak can reliably indicate whether the sample has been exposed to a higher temperature for a longer period of time. This effect could therefore serve to verify compliance with a cold chain.

The measuring point can be small and integrated into a label. It is also possible to create information that can be recognized by the eye. To do this, the treated area must simply be integrated into a hologram that has been exposed in such a way that it reflects the same wavelength. Later color deviations could, for example, make a writing or symbol appear that indicates that the product was exposed to a higher temperature.

Conversely, it is of course also possible for the label to be designed in such a way that the writing or the image disappears over time.

The migration of the castor oil in an underlying absorber layer of the applied hologram label can also serve to indicate the expiry of the minimum shelf life or another period of time via shrinkage and the associated color changes compared to the sealed areas. If the absorber layer is made of paper, the penetration of the castor oil can change the transparency of the paper and produce lettering that can be read independently of the hologram. This effect could also be used to subsequently integrate a kind of watermark on a document. To do this, the appropriately prepared hologram is simply applied to the doument using a heat-sealing process. The conformity of the watermark with the change in the hologram results in a higher level of protection against forgery.

The properties of the photopolymerizable composition that temperature-, pressure- and exposure-dependent phase separations occur between the oil and monomer can be used to create porous lacquer layers. The pore size can be varied via the exposure method and the mixing ratio. The pores are formed by the phase separation of the mixture at the points where the castor oil collects in small bubbles. The unbound castor oil can be washed out after exposure. What remains is a polymer framework whose permeability depends on the structure achieved. The scaffold can of course be filled or coated again with another material to create composite membranes optimised for the application.

The photopolymerizable composition can also be used to produce absorbent microporous layers and may find application for special papers (inkjet printers) or for the absorber layer described above.

The photopolymerizable composition can also be used to produce waterproof and breathable films to replace perfluorinated and polyfluorinated membranes, which are harmful to the environment and health. Preferably, filters for breathing masks with specified pore size can also be produced. The possibility to vary the pore size by exposure can be very helpful to generate multi-level filter layers from coarse to fine. This could prevent premature clogging of the finest membranes.

It is also known that holograms can be used as biosensors for the detection of certain proteins such as toxic proteins, antigens and antibodies.

The use of castor oil has some advantages. Many antigens, such as lipopolysaccharides, have a lipophilic end with which they normally anchor in cell membranes. However, they could also adhere to a transmission hologram in an increased number in those areas where the castor oil is located. The matching antibodies, which then in turn increasingly couple to the antibodies, would locally and periodically change the refractive index and thus the diffraction efficiency of the hologram and could thus be delectated.

The finished element can preferably be used as a label or tag that signals the detection visually to the eye by providing a brightness contrast against the non-active protected hologram portion that is not in contact with the antibodies.

One embodiment could be the use in a respirator that could register the presence of the sought antibody, virus or protein in the breath. Possibly, some kind of patch could also contain such a holographic sensor to detect specific biomolecules on the skin or in the air.

Another object of the invention is a method of forming a light stable hologram in a photopolymerizable layer on a substrate surface, comprising exposing a layer of the photopolymerizable composition according to the invention to modulated radiation carrying holographic information.

Preferably, in the process according to the invention, the exposure to the modulated radiation is carried out by the contact copying method.

Preferably, in the process according to the invention, the photopolymerizable composition is applied and exposed within one minute.

### EXAMPLES

In the following, the invention is explained in more detail by means of examples. A composition according to Table 1 is known from the prior art.

TABLE 1
Comparison example VB1

| Quantity | Quantity | | |
|---|---|---|---|
| [g] | [%] | Designation | CAS |
| 91.93 | 91.93% | SR 349 | 64401-02-1 |
| | | (ethoxylated bisphenol A | |
| | | diacrylate) | |
| 0.03 | 0.03% | Safranin-O | 477-73-6 |
| | | (3,7-diamino-2,8-dimethyl-5- | |
| | | phenyl-phenazinium chloride) | |
| 0.34 | 0.34% | CGI 7460 | |
| | | (Tetrabutylammonium tris(3-flour- | |
| | | phenyl)hexylborate, | |
| | | SEC LCA 1460, BASF) | |
| 3.75 | 3.75% | Castor oil | 8001-79-4 |
| 3.75 | 3.75% | Palm kernel oil | 8023-79-8 |
| 0.2 | 0.20% | Schwego Fluor 8038 | — |
| | | (ethanolic solution of a polyether- | |
| | | based fluorosurfactant) from the | |
| | | Schwegmann company | |
| 100 | 100.00% | | |

The composition is known from EP 1 779 196 B1.

### Examples According to the Invention

Hedipin R/2000 proved to be a better binder for the castor oil to prevent sweating out during exposure.” A waxy ethoxylated castor oil at room temperature. It could be added in smaller quantity than the palm kernel oil with the same effect. This improved the clarity of the exposed mixture. The omission of the Schwego fluorine also brought an improvement in this respect.

Surprisingly, the castor oil content could be significantly increased by adding a small amount of 2,4 dihydroxybenzaldehyde. Which brought a noticeable improvement in the achievable delta-n value. The formulation is described as monomer-containing mixture MM1 in Table 2.

TABLE 2
Monomer-containing mixture MM1

| Quantity | Quantity | | |
|---|---|---|---|
| [g] | [%] | Designation | CAS |
| 35 | 79.46% | SR 349 | 64401-02-1 |
| | | (ethoxylated bisphenol A | |
| | | diacrylate) | |
| 7 | 15.89% | Castor oil | 8001-79-4 |
| 0.2 | 0.45% | SEC LCA 1460 | |
| | | (Tetrabutylammonium tris(3-flour- | |
| | | phenyl)hexylborate) | |
| 0.4 | 0.91% | Irgacure ® OXE01 | 253585-83-0 |
| | | (1,2-octanedione-1-[4-(phenylthio)- | |
| | | phenyl]-2-(O-benzoyloxime) | |
| 0.25 | 0.57% | 2,4 Dihydroxybenzaldehyde | 95-01-2 |
| 1.2 | 2.72% | Hedipine R/2000 | 61791-12-6 |
| | | (PEG-200 castor oil) | |
| 44.05 | 100.00% | | |

A further improvement of the delta-n value or the diffraction efficiency at the same film thickness could be achieved by adding a BPA polymer/poloxamer mixture (see Table 3). It is also advantageous that this reduces the optimum exposure temperature from the previous 25°-26° C. to a common room temperature of 21°-22° C.”

SEC LCA 1460 is only a new name for the original CGI 7460. The dye is added as a solvent-free concentrate (see Table 4) and is not included in the monomer-containing mixtures (Tab. 2 and 3).

TABLE 3
Monomer-containing mixture MM2

| Quantity | Quantity | | |
|---|---|---|---|
| [g] | [%] | Designation | CAS |
| 6 | 12.00% | Poly(bisphenol A-co- | 25036-25-3 |
| | | epichloro-hydrin), glycidyl | |
| | | end-capped, Mₙ ~1,075, | |
| | | Epoxy equivalent weight = | |
| | | 525-550 | |
| 4 | 8.00% | Poly(ethylene glycol)-block- | 9003-11-6 |
| | | poly(propylene glycol)-block- | |
| | | poly(ethylene glycol) | |
| | | Mₙ ~1,100 | |
| 40 | 80.00% | Monomer-containing mixture | |
| | | MM1 | |
| 50 | 100.00% | | |

TABLE 4
Dye concentrate FK1

| Quantity | Quantity | | |
|---|---|---|---|
| [g] | [%] | Designation | CAS |
| 0.97 | 4.85% | EFKA PX 4701 | |
| | | acrylic block copolymer from | |
| | | the company BASF | |
| 1.94 | 9.70% | N-hydroxyethylacrylamide | 7646-67-5 |
| 16.45 | 82.25% | PEG-200, Mₙ □200 | 25322-68-3 |
| 0.64 | 3.2% | Methylene blue | 61-73-4 |
| 20 | 100.00% | | |

For the exposures of samples A, B and C, the following photopolymerizable compositions were prepared from the monomer-containing mixtures and dye concentrate listed above. The known formulation from Table 1 without the safranin-O was used as a comparative example. Instead of Safranin-O, the colour concentrate FK1 with methylene blue was also added to mixture A.

Samples D, E and F were only cured with UV light. Therefore, only the UV photoinitiator Omnirad 1173 was added instead of the dye concentrate.

TABLE 5
Photopolymerizable composition A

| Quantity | Quantity | | |
|---|---|---|---|
| [g] | [%] | Component | Name |
| 5 | 97.09% | VB1 | Monomer-containing |
| | | without Safranin-O | mixture from the |
| | | | comparative example |
| 0.15 | 2.91% | FK1 | Dye concentrate |
| 5.15 | 100.00% | | |

TABLE 6
Photopolymerizable composition B

| Quantity | Quantity | | |
|---|---|---|---|
| [g] | [%] | Component | Name |
| 5 | 97.09% | MM1 | Monomer-containing mixture |
| 0.15 | 2.91% | FK1 | Dye concentrate |
| 5.15 | 100.00% | | |

TABLE 7
Photopolymerizable composition C

| Quantity | Quantity | | |
|---|---|---|---|
| [g] | [%] | Component | Name |
| 5 | 97.09% | MM2 | Monomer-containing mixture |
| 0.15 | 2.91% | FK1 | Dye concentrate |
| 5.15 | 100.00% | | |

TABLE 8
Photopolymerizable composition D

| Quantity | Quantity | | |
|---|---|---|---|
| [g] | [%] | Component | Name |
| 5 | 97.09% | VB1 | Monomer-containing |
| | | without Safranin-O | mixture from the |
| | | | comparative example |
| 0.1 | 1.96% | Omnirad 1173 | Photoinitiator |
| 5.1 | 100.00% | | |

TABLE 9
Photopolymerizable composition E

| Quantity | Quantity | | |
|---|---|---|---|
| [g] | [%] | Component | Name |
| 5 | 97.09% | MM1 | Monomer-containing mixture |
| 0.1 | 1.96% | Omnirad 1173 | Photoinitiator |
| 5.1 | 100.00% | | |

TABLE 10
Photopolymerizable composition F

| Quantity | Quantity | | |
|---|---|---|---|
| [g] | [%] | Component | Name |
| 5 | 97.09% | MM2 | Monomer-containing mixture |
| 0.1 | 1.96% | Omnirad 1173 | Photoinitiator |
| 5.1 | 100.00% | | |

### Preparation

First, the color concentrates and the monomer-containing mixtures are prepared. The respective components are added one after the other into a beaker with a stirring magnet. The beaker is placed on a scale for this purpose so that the liquid substances can be added in the correct quantity. Then everything is heated to 120° C. on a heatable magnetic stirrer and stirred. The powdery substances are dosed with the help of weighing bowls and added to the mixture while stirring. The mixture is stirred at 120° C. for about 1 h before the solution is filtered and filled into a bottle.

The dye concentrates and the monomer-containing mixtures are mixed (for example by shaking with a speed mixer or stirring with a stirring rod) to form the photopolymerizable compositions according to the invention.

### Exposures

TABLE 11
Laser exposures

| | Peak [nm] | BWG[%] | Peak | BWG[%] | | |
|---|---|---|---|---|---|---|
| | after laser | after laser | [nm] after | after | Thickness | |
| Material | exposure | exposure | sealing | sealing | [μm] | Δn |
| A | 576 | 67% | 572 | 52% | 12 | 0.0138 |
| B | 577 | 84% | 573 | 78% | 12 | 0.0211 |
| C | 581 | 93% | 578 | 90% | 12 | 0.0279 |

The photopolymerizable compositions A, B, C were kept in an oven at 80° C. and exposed shortly after application. They were exposed to a laser with a wavelength of 577 nm in a temperature range of 20° C. to 21° C. After laser exposure, the diffraction efficiency (BWG) was determined using a spectrometer based on the spectral absorption curve. The film thickness was measured with a digital micrometer outside micrometer gauge. Afterwards, the photopolymerized compositions were sealed with a UV varnish (e.g. a 99 wt % bisphenol A diacrylate (e.g. SR 349 from Table 1) +1 wt % photoinitiator (Omnirad 1173)). The varnish was cured under a UV bridge with an arc length of 70 mm and a power of 120 W/cm. The irradiation time was 30s. Afterwards, the spectral absorption curve was measured again and the BWG was determined. Based on the layer thickness and the BWG's η, the Δn was calculated. For this purpose, the Kogelnik formula (F-1) was resolved to Δn as follows.

$$Δ n = \frac{λ}{π \cdot d} atanh ( \sqrt{η} ) \qquad ( F - 2 )$$

To show the exposure-dependent haze effect, samples D, E and F were cured with UV light sources of different strengths. For fast curing, the UV bridge described above was used again. Although a much shorter time is sufficient for curing, the samples were irradiated for 30 s. For the slow exposure, the Hamamatsu UV spot light source LC6 was used. The UV light exits at the end of a flexible light guide with the intensity of 3.5 W/cm₂. The samples were exposed for 120 s at a distance of 6 cm from the exit aperture. Afterwards, to be on the safe side, they were post-cured for another 30 s under the UV bridge.

TABLE 12
UV exposures

| | | Sample | | Sample | | |
|---|---|---|---|---|---|---|
| | | thickness | | thickness | | |
| | Haze value | of the slow | Haze value | of the fast | | |
| | of the slow | exposure | of the fast | exposure | Haze | Temperature |
| Material | exposure | sample | exposure | [μm] | difference | [° C.] |
| D | 82% | 948 | 2% | 936 | 80% | 26 |
| D | 89% | 890 | 70% | 855 | 19% | 21 |
| E | 95% | 952 | 16% | 928 | 79% | 21 |
| F | 99% | 938 | 25% | 962 | 74% | 21 |

The photopolymerizable compositions for the UV exposures were kept at a room temperature of 21° C. For the first exposure only, the reference material D was kept and processed at 26° C. The second exposure at 21° C. with material D has a high haze value of 70% despite fast exposure, because at this temperature the liquid formulation is already milky.

For the haze exposure tests, the photopolymerizable compositions were added with a pipette as a thick drop in the middle of one object glass and covered with a second object glass. In order to obtain a layer thickness of approximately 0.9 mm, spacers of this thickness were placed on the right and left of the first glass. The whole thing was then fixed with clamps attached to the sides.

After curing, the clamps can be loosened and the glass plates removed so that the thickness and haze of the photopolymer layer can be determined.

### Exposure Structure

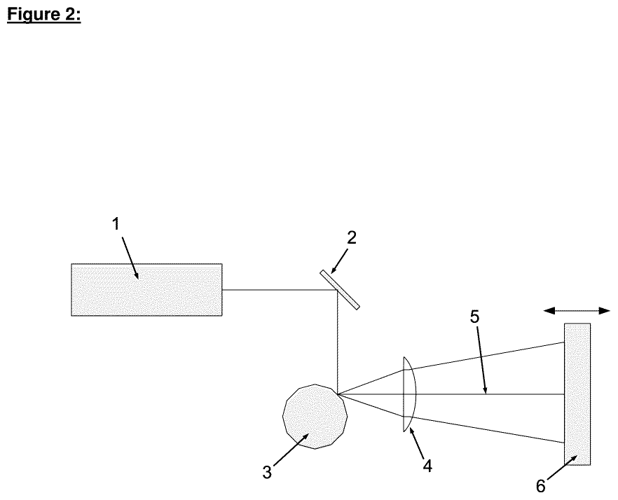

The laser beam with a measured power of 1.43 W was expanded horizontally with a polygon scanner and focused by a cylindrical lens so that it covered an exposure width of 23 cm. FIG. 2 shows the schematic exposure setup.

### Reference Signs in FIG. 2

1 Laser 577 nm
2 Mirror
3 Polygon scanner
4 Cylinder lens
5 Scanning beam
6 Scanner mirror

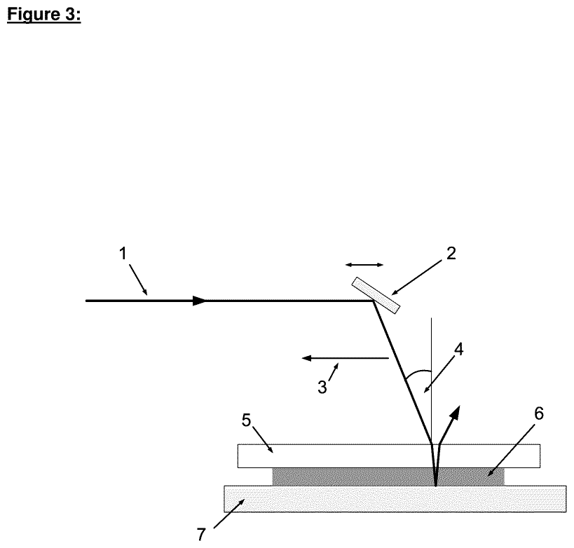

The respective samples A, B and C were scanned with this line using a movable mirror and exposed. The traversing speed was set to 9 mm/s. The laser beam fell on the sample surface at an angle of 22° to the perpendicular. FIG. 3 shows the beam path.

### Reference Signs in FIG. 3

1 Scanning beam 577 nm
2 Scanner mirror
3 Exposure direction
4 Exposure angle, 22°
5 Substrate, glass or foil
6 Photopolymer (photopolymerizable composition)
7 Master, mirror plate

To create a reflection hologram, the sample material was applied to a mirror plate that reflects the laser light back. The interference of the incident beam with the reflected beam creates a line pattern of light and dark spots parallel to the surface of the mirror. This interference pattern is recorded by the material in the form of a refractive index modulation and a so-called Lippmann-Bragg hologram is created.

With laser exposure, the photopolymer layer is between the mirror sheet and a transparent substrate, e.g. a PET film or glass. For the examples, an approximately 75 μm thick PET film of the brand Melinex from the company DuPont was used. The coating was applied by laminating the film with a rubber roller. The thickness of the layer is determined by the contact pressure, the temperature and the speed of travel.

After laser exposure, the material is still cured with UV light. For the first curing step we use a UV flash with a power of 3000 WS. This is sufficient to remove the hologram with the carrier from the sheet afterwards.

Afterwards, the hologram can be sealed with a UV varnish layer. For curing the UV varnish we use a UV bridge with an arc length of 70 mm and a power of 120 W/cm.

### Measurement Setup

The laser exposure samples A, B and C were measured with a spectrometer (CAS 140 B from Instrument Systems) in transmitted light. This was done with perpendicular illumination. Since the hologram only reflects the wavelength that fulfils the Bragg condition, a clear absorption peak can be seen in the spectral curve at this point.

From the peak value TPeak and a nearby reference value TRef on the upper baseline, the diffraction efficiency (BWG) n is calculated as follows:

η=(T_{Ref}−T_{Peak})/T_{Ref}

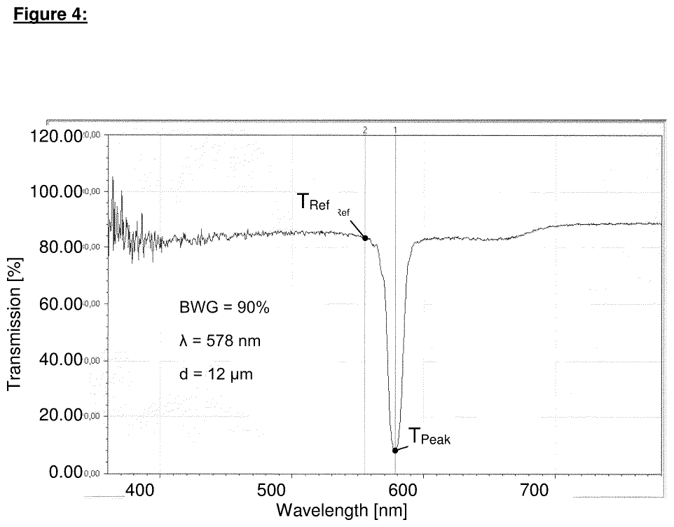

FIG. 4 shows the measurement curve with the corresponding measurement points of the first exposure of sample C.

The table values of the exposures (Tab. 11) show that samples B and C achieve a higher diffraction efficiency and a better Δn-value than the comparison mixture A at the same layer thickness.

The haze values of the UV exposure samples D, E and F were measured with a hazemeter (haze-gard i from BYK) using a 4 mm aperture diaphragm according to the ASTM D 1003 standard procedure. The table values (Tab. 12) show that different turbidities can be achieved by different exposure intensities. With a layer thickness of about 0.9 mm, the difference can be more than 70%. The two measurements of the comparison sample D show that the exposure temperature also has an influence. In contrast to the compositions E and F according to the invention, the liquid comparison mixture D is not clear at 21° C.

### Manufacturing

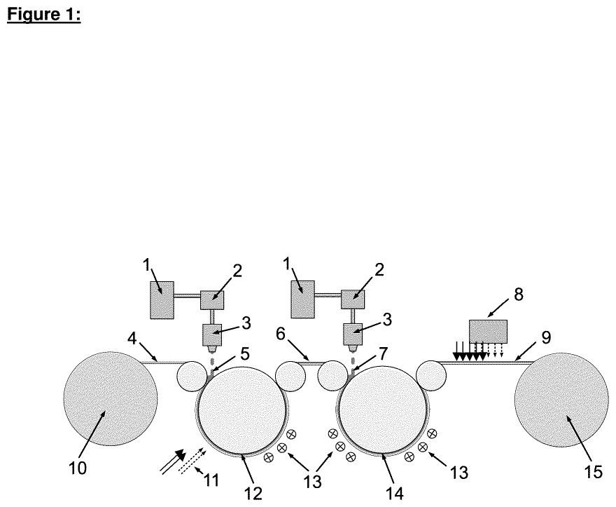

FIG. 1 shows the schematic construction of a compact roll-to-roll machine for the production of sealed holographic contact copies from the claimed photopolymerizable compositions.

### Reference Signs in FIG. 1

1 Storage container
2 Filter and degasser
3 Dosing unit
4 Support foil
5 Photopolymer (photopolymerizable composition)
6 Support foil with hologram
7 UV varnish
8 UV emitter
9 Support foil with sealed and bleached hologram
10 Foil unwinding
11 Laser light
12 Master
13 UV light
14 polished metal drum
15 Foil winder

1-15. (canceled)

16. A photopolymerizable composition comprising:
I) a first mixture A comprising:
a) at least one monomer M comprising at least one ethylenically unsaturated group,
b) at least one triglyceride and/or a modified triglyceride,
c) at least one photoinitiator,
d) at least one aromatic aldehyde and/or aliphatic aldehyde; and
e) optionally an additive.

17. The photopolymerizable composition of claim 16, comprising:
I) a first mixture A comprising:
a) at least one monomer M comprising at least one ethylenically unsaturated group,
b) at least one triglyceride and/or a modified triglyceride,
c) at least one photoinitiator,
d) at least one aromatic aldehyde and/or aliphatic aldehyde; and
e) optionally an additive, and
II) at least one polyether.

18. The photopolymerizable composition of claim 16, comprising:
I) a first mixture A comprising:
a) at least one monomer M comprising at least one ethylenically unsaturated group,
b) at least one triglyceride and/or a modified triglyceride,
c) at least one photoinitiator,
d) at least one aromatic aldehyde and/or aliphatic aldehyde; and
e) optionally an additive, and
II) at least one polyether,
wherein the photopolymerizable composition is liquid at a standard pressure in the range of 15° C. to 150° C.

19. The photopolymerizable composition of claim 16, comprising:
I) 60%-95% by weight of a first mixture A comprising:
a) at least one monomer M comprising at least one ethylenically unsaturated group,
b) at least one triglyceride and/or a modified triglyceride,
c) at least one photoinitiator,
d) at least one aromatic aldehyde and/or aliphatic aldehyde; and
e) optionally an additive, and
II) 5%-40% by weight of at least one polyether,
wherein the amounts of I) and II) add up to 100% by weight.

20. The photopolymerizable composition of claim 16, comprising:
I) 60%-95% by weight of a first mixture A comprising:
a) 70%-98% by weight of at least one monomer M comprising at least one ethylenically unsaturated group,
b) 0.5%-24% by weight of at least one triglyceride and/or a modified triglyceride,
c) 0.1%-5% by weight of at least one photoinitiator,
d) 0.1%-2% by weight of at least one aromatic aldehyde and/or aliphatic aldehyde, and
e) 0% to 10% by weight of an additive, wherein the amounts of a) to e) add up to 100% by weight, and
II) 5%-40% by weight of at least one polyether,
wherein the amounts of I) and II) add up to 100% by weight.

21. An element comprising a component obtainable by the action of UV/VIS radiation on the photopolymerizable composition of claim 16.

22. The element of claim 21, comprising a component having transparent and/or translucent regions.

23. The element of claim 21, comprising a hologram obtainable by exposing the photopolymerizable composition to modulated radiation carrying holographic information.

24. The element of claim 23, comprising a hologram, wherein the hologram is provided with a sealing layer.

25. The element of claim 24, wherein a swelling agent is applied to the sealing layer.

26. A foil, lens, grating, prism, mirror, beam splitter, diffuser, surface relief, membrane, filter or sensor comprising the element according to claim 21.

27. A head-up display, data glasses, light guidance system, spectrometer, detection system, security element or label comprising the element according to claim 21.

28. A method of forming a light stable hologram in a photopolymerizable layer on a substrate surface, comprising exposing a layer of the photopolymerizable composition of claim 16 to modulated radiation carrying holographic information.

29. The method of claim 28, wherein the exposure to the modulated radiation is by contact copying.

30. The method of claim 28, wherein the photopolymerizable composition is applied and exposed within one minute.

31. The element of claim 21, wherein the UV/VIS radiation is actinic UV/VIS radiation.
